(19) United States
(12) Patent Application Publication
(10) Pub. No.: US 2013/0118788 A1
(43) Pub. Date: May 16, 2013

(54) POLYIMIDE PRECURSOR COMPOSITION, AND WIRING CIRCUIT BOARD EMPLOYING THE COMPOSITION

(71) Applicants: Tomoaki Hishiki, Ibaraki-shi (JP); Takami Hikita, Ibaraki-shi (JP); Takatoshi Sakakura, Ibaraki-shi (JP)

(72) Inventors: Tomoaki Hishiki, Ibaraki-shi (JP); Takami Hikita, Ibaraki-shi (JP); Takatoshi Sakakura, Ibaraki-shi (JP)

(73) Assignee: NITTO DENKO CORPORATION, Osaka (JP)

(21) Appl. No.: 13/609,864

(22) Filed: Sep. 11, 2012

(30) Foreign Application Priority Data
Nov. 10, 2011 (JP) 2011-246093

(51) Int. Cl. C09D 177/10; H05K 1/03

(52) U.S. Cl. 174/258; 524/600

(57) ABSTRACT

A polyimide precursor composition comprises (A), and at least one of (B) and (C), (B) and (C) being present in a proportion of 30-100 parts by weight based on 100 parts by weight of (A):
(A) a polyimide precursor comprising:
(a1) a unit of formula (1):

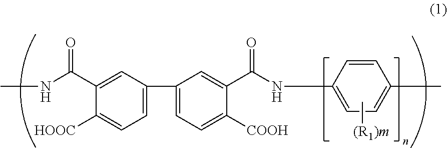

R₁ is a C₁-C₃ alkyl group connected to an aromatic ring, m is 0 or not greater than 4, and n is 1 to 4; and
(a2) a unit of formula (2):

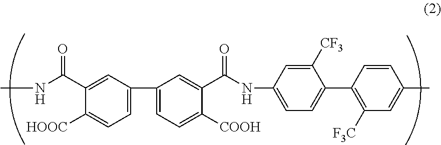

(a1) and (a2) are present in a molar ratio of 20/80 to 70/30;
(B) a compound of formula (3):
R₂ is a hydrogen atom or a methyl group, and R₃ is a

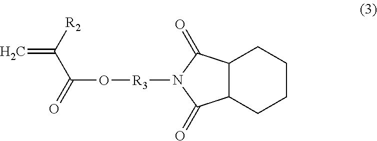

divalent hydrocarbon group having two or more carbon atoms; and
(C) a compound of formula (4):
R₄ is a hydroxyl group or a methoxy group, R₅ is a hydrogen

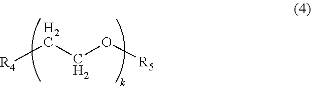

atom or a methyl group, and k is 4-23.

### BACKGROUND OF THE INVENTION

1. Field of the Invention

The present invention relates to a polyimide precursor composition which provides a polyimide material to be used, for example for a hard disk drive suspension board, and to a wiring circuit board produced by using the polyimide precursor composition. The polyimide material has a lower linear expansion coefficient and a lower hygroscopic expansion coefficient, suppresses warpage attributable to the influence of temperature and humidity, permits polyimide etching (PI etching), and prevents separation in an interface between a cured polyimide film and a wiring circuit pattern of a wiring circuit board.

2. Description of the Related Art

In recent years, hard disk drives (hereinafter often abbreviated as “HDD”) to be incorporated in personal computers are required to have a higher capacity and a higher information transmission speed. Such an HDD includes a so-called magnetic head, and a so-called magnetic head suspension which supports the magnetic head.

With a recent rapidly-increasing demand for the higher capacity, the HDD is required to access a minute region for performing data reading and writing operations, so that a distance between the magnetic head and a disk tends to be reduced. For precise control of the distance between the magnetic head and the disk, a polyimide photosensitive material having a lower linear expansion coefficient and a lower hygroscopic expansion coefficient is used instead of a conventional epoxy resin photosensitive material as an insulative resin for formation of a wiring circuit board in the magnetic head.

Further, wirings of the wiring circuit are arranged at a higher density to reduce a characteristic impedance and, therefore, are designed so as to have a smaller inter-wiring distance and a greater film thickness relative to the wiring circuit board.

On the other hand, HDDs to be incorporated in a variety of smaller-size devices such as portable devices are increasingly demanded to satisfy various requirements. A disk of such an HDD for recording information has a correspondingly smaller size (diameter) and a correspondingly higher recording density. In order to access a track of the smaller-diameter disk for the data reading and writing operations, the disk should be slowly rotated, so that the relative speed (circumferential speed) of the disk with respect to the magnetic head is reduced. Therefore, the suspension board should be moved toward the disk with a smaller force. Accordingly, the suspension board is required to have a lower rigidity.

The suspension board of the HDD typically includes a metal support, an insulative layer, a wiring layer and a cover layer, which are patterned and stacked in this order. A conceivable method for imparting the suspension board with a lower rigidity is to reduce the residual proportion of the relatively rigid metal substrate serving as the metal support. If the residual proportion of the rigid metal support is reduced, however, the suspension board is liable to warp. To cope with this problem, JP-A-2008-310946 proposes that a polyimide precursor having a lower hygroscopic expansion coefficient is used as a material for formation of the insulative layer and the cover layer to suppress the warpage. Japanese Patent No. 3332278 proposes that a wiring circuit board of a thin-film multilayer substrate having a lower linear expansion coefficient is produced by using a polyimide precursor that is unlikely to suffer from accumulation of interlayer residual stress.

However, a polyimide formed from the polyimide precursor is unsatisfactory because the hygroscopic expansion coefficient is not sufficiently reduced. Further, the polyimide precursor should be further improved for improvement of the levitation stability of the magnetic head above the disk. For the reduction in the hygroscopic expansion coefficient of the polyimide, JP-A-2010-276775 proposes a method of introducing fluorine into a polyimide structure.

Where fluorine is introduced into the polyimide structure as stated in JP-A-2010-276775, however, the linear expansion coefficient of the polyimide is disadvantageously increased. Further, unless the insulative layer and the metal support have substantially the same linear expansion coefficient, the board is liable to warp, and the insulative layer and the metal support are separated from each other. Therefore, where copper or a stainless steel alloy is used for the metal support, the amount of fluorine to be introduced into the polyimide structure should be reduced to impart the polyimide insulative layer and the metal support with substantially the same linear expansion coefficient. This results in insufficient reduction of the hygroscopic expansion coefficient of the polyimide. Further, the insulative layer and the wiring layer are liable to be separated from each other due to the smaller inter-wiring distance of the wiring circuit board and the greater wiring thickness as well as a shrinkage stress occurring when the polyimide insulative layer is cured.

### SUMMARY OF THE INVENTION

A polyimide precursor composition is provided which reduces the hygroscopic expansion coefficient of a polyimide insulative resin material without increasing the linear expansion coefficient of the polyimide material, prevents the cured polyimide insulative resin material from being separated from wirings of an electrically conductive circuit pattern having a reduced inter-wiring distance and an increased wiring thickness, and permits excellent PI etchability. It is another object of the present invention to provide a wiring circuit board produced by using the polyimide precursor composition.

According to a first aspect, there is provided a polyimide precursor composition, which comprises the following component (A), and at least one of the following components (B) and (C), wherein the at least one of the components (B) and (C) is present in a proportion of 30 to 100 parts by weight based on 100 parts by weight of the component (A):
(A) a polyimide precursor comprising:
(a1) a structural unit represented by the following general formula (1):

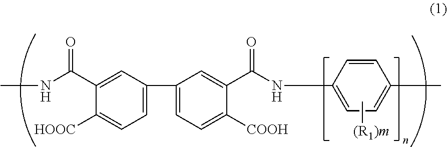

wherein R₁ is a C₁ to C₃ alkyl group and connected to an aromatic ring, m is a positive integer of 0 or not greater than 4, and n is an integer of 1 to 4; and
(a2) a structural unit represented by the following general formula (2):

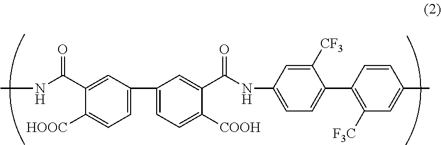

wherein the structural unit (a1) represented by the above general formula (1) and the structural unit (a2) represented by the above general formula (2) are present in a molar ratio of (a1)/(a2)=20/80 to 70/30;
(B) an imide acrylate compound represented by the following general formula (3):

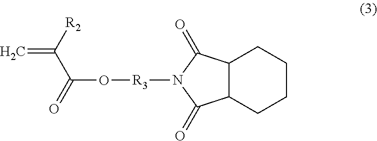

wherein R₂ is a hydrogen atom or a methyl group, and R₃ is a divalent hydrocarbon group having two or more carbon atoms; and
(C) a polyethylene glycol compound represented by the following general formula (4):

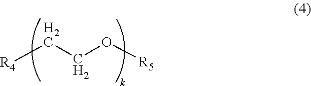

wherein R₄ is a hydroxyl group or a methoxy group, R₅ is a hydrogen atom or a methyl group, and k is a positive number of 4 to 23.

According to a second aspect, there is provided a wiring circuit board, which includes a wiring circuit substrate having an electrically conductive circuit pattern provided on a surface thereof, and a polyimide precursor composition layer formed on the surface of the wiring circuit substrate by applying a solution of the polyimide precursor composition described above on the surface.

According to a third aspect, there is provided a wiring circuit board, which includes a wiring circuit substrate having an electrically conductive circuit pattern provided on a surface thereof, and a polyimide resin insulative layer formed from the polyimide precursor composition described above on the surface of the wiring circuit substrate and patterned in a predetermined pattern by a wet etching process.

A polyimide precursor composition which permits reduction in the hygroscopic expansion coefficient of a cured polyimide material without increasing the linear expansion coefficient of the polyimide material, prevents the cured polyimide material from being separated from wirings, and has excellent PI etchability can be achieved by using the polyimide precursor composition which comprises the specific polyimide precursor (A) comprising the structural unit represented by the above general formula (1) and the structural unit represented by the above general formula (2) with these structural units being present in the predetermined molar ratio, and the predetermined amount of the at least one of the imide acrylate compound (B) represented by the above general formula (3) and the polyethylene glycol compound (C) represented by the above general formula (4).

As described above, the polyimide precursor composition comprises the specific polyimide precursor (A) comprising the structural unit represented by the above general formula (1) and the structural unit represented by the above general formula (2) with these structural units being present in the predetermined molar ratio, and the predetermined amount of the at least one of the imide acrylate compound (B) represented by the above general formula (3) and the polyethylene glycol compound (C) represented by the above general formula (4). The wiring circuit board includes the polyimide precursor composition layer formed by applying the solution of the polyimide precursor composition on the surface of the wiring circuit substrate formed with the electrically conductive circuit pattern, and the wiring circuit board which includes the polyimide resin insulative layer formed from the polyimide precursor composition on the surface of the wiring circuit substrate formed with the electrically conductive circuit pattern and patterned in the predetermined pattern by the wet etching process. Therefore, the formed polyimide resin insulative layer has a lower linear expansion coefficient and a lower hygroscopic expansion coefficient, is free from the separation between the cured polyimide material and the electrically conductive circuit pattern, and has excellent PI etchability.

### DETAILED DESCRIPTION OF THE INVENTION

Embodiments of the present invention will hereinafter be described.

The polyimide precursor composition contains a specific polyimide precursor (A), at least one of a specific imide acrylate compound (B) and a specific polyethylene glycol compound (C), and a pyridine photosensitive agent.

### <<Specific Polyimide Precursor (A)>>

The specific polyimide precursor (A) is a polyimide precursor (polyamic acid) having:

a structural unit represented by the following general formula (1):

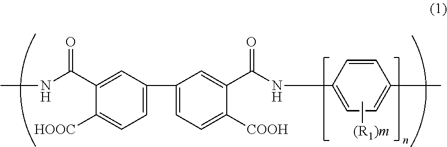

wherein R₁ is a C₁ to C₃ alkyl group and connected to an aromatic ring, m is a positive integer of 0 or not greater than 4, and n is an integer of 1 to 4; and

a structural unit represented by the following general formula (2):

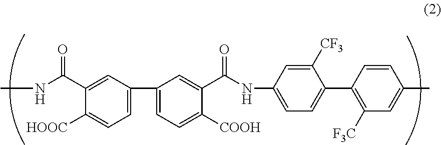

The specific polyimide precursor including the structural units respectively represented by the above general formulae (1) and (2) experiences an imidization reaction through an ordinary imidization process (e.g., thermal cyclization or chemical cyclization using pyridine anhydride) to form closed imide rings to provide a polyimide.

In the structural unit represented by the above general formula (1), the repetition number m is preferably 0, and the repetition number n is preferably 1.

The specific polyimide precursor including the structural units represented by the above general formulae (1) and (2) is obtained by allowing a tetracarboxylic acid component and a diamine component to react with each other in an organic solvent.

An example of the tetracarboxylic acid component is 3,3′,4,4′-biphenyltetracarboxylic dianhydride.

At least two diamines should be used as the diamine component. A first diamine is an aromatic diamine having an aromatic ring such as benzene, biphenyl, triphenyl, terphenyl, toluene, xylene or tolidine. A specific example of the first diamine is p-phenylenediamine.

A second diamine is a fluorination and methylation product of benzidine. A specific example of the second diamine is 2,2′-bis(trifluoromethyl)-4,4′-diaminobiphenyl.

The molar ratio between the first diamine and the second diamine to be used as the diamine component is the first diamine (a1)/the second diamine (a2)=20/80 to 70/30, preferably 50/50 to 60/40. If the amount of the first diamine (a1) is excessively great, the hygroscopic expansion coefficient is not sufficiently reduced. If the amount of the first diamine (a1) is excessively small, the linear expansion coefficient is excessively high. If the amount of the second diamine (a2) is excessively small, an insulative layer formed from the resulting polyimide precursor composition on a wiring circuit board having a smaller inter-wiring distance and a greater wiring thickness is liable to be separated from wirings. Other tetracarboxylic acids and other diamines may be used in combination for preparation of the specific polyimide precursor (A), as long as it includes the aforementioned structural units and does not adversely influence the linear expansion coefficient, the elastic modulus and the like.

Examples of the organic solvent include N-methyl-2-pyrrolidone, dimethylacetamide, dimethyl sulfoxide, dimethylformamide and hexamethylphosphoramide, which may be used either alone or in combination.

In the specific polyimide precursor (A), the molar ratio between the structural unit (a1) represented by the above general formula (1) and the structural unit (a2) represented by the above general formula (2) should be (a1)/(a2)=20/80 to 70/30, preferably 50/50 to 60/40. If the amount of the structural unit represented by the general formula (1) is excessively great in the overall amount of the polyimide precursor, the hygroscopic expansion coefficient is not sufficiently reduced. If the amount of the structural unit represented by the general formula (1) is excessively small, the linear expansion coefficient is excessively great.

### <<Specific Imide Acrylate Compound (B)>>

The specific imide acrylate compound (B) is a compound represented by the following general formula (3):

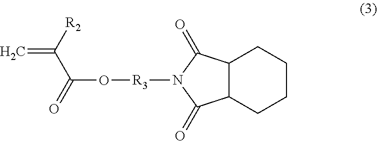

wherein R₂ is a hydrogen atom or a methyl group, and R₃ is a divalent hydrocarbon group having two or more carbon atoms.

In the formula (3), R₃ is preferably an alkylene group. Particularly preferably, R₂ is a hydrogen atom, and R₃ is an ethylene group. A specific example of the imide acrylate compound (B) is N-acryloyloxyethyl hexahydrophthalimide.

The proportion of the specific imide acrylate compound (B) is determined so that the proportion of at least one of the specific imide acrylate compound (B) and the specific polyethylene glycol compound (C) is 30 to 100 parts by weight based on 100 parts by weight of the specific polyimide precursor (A). If only the specific imide acrylate compound (B) is used out of these compounds (B) and (C), the proportion of the specific imide acrylate compound (B) is 30 to 100 parts by weight based on 100 parts by weight of the specific polyimide precursor (A). If the proportion of the component (B) is excessively small, it is impossible to sufficiently reduce the linear expansion coefficient. If the proportion of the component (B) is excessively great, on the other hand, the thickness of the resulting polyimide resin layer is remarkably reduced during a heat treatment.

### <<Specific Polyethylene Glycol Compound (C)>>

The specific polyethylene glycol compound (C) is a compound represented by the following general formula (4):

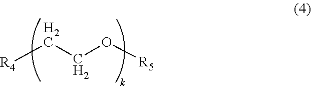

wherein R₄ is a hydroxyl group or a methoxy group, R₅ is a hydrogen atom or a methyl group, and k is a positive number of 4 to 23.

Examples of the compound represented by the above formula (4) include: (1) a compound having OH groups at opposite terminals (i.e., R₄ is a hydroxyl group and R₅ is a hydrogen atom); (2) a compound having a methoxy group at one of opposite terminals and a hydrogen atom at the other terminal (i.e., R₄ is a methoxy group and R₅ is a hydrogen atom); and (3) a compound having a methoxy group at one of opposite terminals and a methyl group at the other terminal (i.e., R₄ is a methoxy group and R₅ is a methyl group). Preferably, R₄ is a hydroxyl group, R₅ is a hydrogen atom, and the repetition number k is a positive number of 4 to 23, as described above, in the formula (4).

The specific polyethylene glycol compound (C) has a weight average molecular weight of 200 to 1000, particularly preferably 200 to 400. The weight average molecular weight is determined by gel permeation chromatography (GPC) based on polyethylene oxide calibration standards.

The proportion of the specific polyethylene glycol compound (C) is determined so that the proportion of at least one of the specific imide acrylate compound (B) and the specific polyethylene glycol compound (C) is 30 to 100 parts by weight based on 100 parts by weight of the specific polyimide precursor (A). If only the specific polyethylene glycol compound (C) is used out of these compounds (B) and (C), the proportion of the specific polyethylene glycol compound (C) is 30 to 100 parts by weight based on 100 parts by weight of the specific polyimide precursor (A). If the proportion of the component (C) is excessively small, it is impossible to sufficiently reduce the linear expansion coefficient. If the proportion of the component (C) is excessively great, the thickness of the resulting polyimide resin layer is remarkably reduced during a heat treatment.

Where at least one of the specific imide acrylate compound (B) and the specific polyethylene glycol compound (C) is to be used in combination with the specific polyimide precursor (A), only one of the specific imide acrylate compound (B) and the specific polyethylene glycol compound (C) is typically used for costs. For excellent PI etchability, only the specific imide acrylate compound (B) is generally used out of the compounds (B) and (C).

### <<Pyridine Photosensitive Agent>>

For preparation of the polyimide precursor composition, the pyridine photosensitive agent is used in combination with the components (A) to (C) to impart the composition with photosensitivity in consideration of the use purpose and the properties of the composition and the like.

An example of the pyridine photosensitive agent is a compound represented by the following general formula (5):

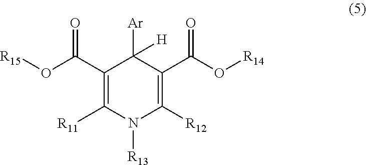

wherein R₁₁, R₁₂, R₁₃, R₁₄ and R₁₅, which may be the same or different, are each a hydrogen atom or a C₁ to C₄ alkyl group, and Ar is an aryl group having a nitro group at its ortho position.

In the formula (5), it is preferred that R₁₁ and R₁₂ are each a hydrogen atom or a methyl group, R₁₃ is a methyl group or an ethyl group, and R₁₄ and R₁₅ are each a methyl group or an ethyl group. In the formula (5), Ar is an aryl group having a nitro group at its ortho position. A specific example of Ar is 2-nitrophenyl group.

The pyridine derivative serving as the pyridine photosensitive agent represented by the above general formula (5) is prepared, for example, in the following manner. The preparation of the pyridine derivative represented by the above general formula (5) is achieved, for example, by causing a substituted benzaldehyde and an alkyl propiolate (alkyl propargylate) which are used in a molar ratio of 1:2 and a corresponding primary amine to react with each other in glacial acetic acid with refluxing (see Khim. Geterotskl. Soed., pp. 1067 to 1071, 1982) or by introducing an ester group into a corresponding 1,4-dihydropyridine derivative such as 4-o-nitrophenyl-3,5-dimethoxycarbonyl-1,4-dihydropyridine through N-alkylation and selectively hydrolyzing the ester group.

The molecular structure of the pyridine photosensitive agent is changed into a structure having a pyridine skeleton by irradiation with activation radiation such as ultraviolet radiation to exhibit basicity, so that the thermal imidization of the specific polyimide precursor is facilitated in an exposed portion of the polyimide precursor composition film. The chemical reaction thereafter further proceeds in the subsequent heat treatment, whereby the solubility of a photoreaction product of the pyridine photosensitive agent in an organic solvent is reduced. These effects reduce the alkali solubility of the exposed portion. This makes a difference in dissolution speed between the exposed portion and an unexposed portion of the polyimide precursor composition film, whereby a desired pattern can be advantageously formed.

The amount of the pyridine photosensitive agent to be used is preferably 5 to 70 parts by weight, particularly preferably 10 to 55 parts by weight, based on 100 parts by weight of the specific polyimide precursor (A). If the amount of the pyridine photosensitive agent is excessively small, the exposed portion is liable to have a poorer dissolution preventing capability in forming a pattern, thereby reducing the solubility contrast. If the amount of the pyridine photosensitive agent is excessively great, the resulting polyimide precursor composition is liable to suffer from solid deposition when being stored in a solution form, i.e., is liable to have poorer solution storage stability. After a film formed from the resulting polyimide precursor composition is patterned and heat-treated, the film tends to have a significantly reduced film thickness and a lower mechanical strength.

The polyimide precursor composition may contain a sensitizer, as required, in addition to the components (A) to (C) and the pyridine photosensitive agent. The polyimide precursor composition may further contain a dissolution accelerator which increases a dissolution rate at which the unexposed portion is dissolved away with the use of a developing liquid. The dissolution accelerator is inactive with respect to the activation radiation. The dissolution accelerator is advantageous in practice, because it improves the developing speed when being contained in the polyimide precursor composition.

Examples of the dissolution accelerator include 2,6-dimethyl-3,5-dicyano-4-methyl-1,4-dihydropyridine and 2,6-dimethyl-3,5-dicyano-1,4-dihydropyridine. In the polyimide precursor composition, the dissolution accelerator is preferably present in a proportion of 5 to 50 parts by weight, particularly preferably 5 to 15 parts by weight, based on 100 parts by weight of the polyimide precursor (A).

The polyimide precursor composition is prepared, for example, by synthesizing the specific polyimide precursor (A) and then blending and mixing the polyimide precursor (A) with at least one of the specific imide acrylate compound (B) and the specific polyethylene glycol compound (C), further with the pyridine photosensitive agent and, optionally, with other ingredients (the sensitizer, the dissolution accelerator and the like).

### <<Physical Properties of Polyimide Resin Film>>

A polyimide resin film formed from the polyimide precursor composition thus prepared preferably has a hygroscopic expansion coefficient of 0 to 20 ppm/% RH and a linear expansion coefficient of 0 to 20 ppm/° C. More preferably, the polyimide resin film has a hygroscopic expansion coefficient of 0 to 12 ppm/% RH and a linear expansion coefficient of 15 to 20 ppm/° C. If the linear expansion coefficient and the hygroscopic expansion coefficient fall outside the aforementioned ranges, there are significant differences in linear expansion coefficient and hygroscopic expansion coefficient between the polyimide resin film and a metal material of a wiring circuit board. Therefore, the wiring circuit board tends to suffer from warpage due to an interlayer stress.

The linear expansion coefficient is measured, for example, in the following manner. A polyimide resin film is formed from the polyimide precursor composition, and a test sample having a width of 5 mm and a length of 20 mm is cut out of the film. With the use of a thermomechanical analyzer (THERMO PLUS TMA8310 available from Rigaku Corporation), the linear expansion coefficient of the test sample is measured under the following conditions. The elongation of the test sample is measured along a measurement length of 15 mm in a temperature range of 100° C. to 250° C. with a tensile load of 49 mN while the temperature is increased at a rate of 5° C./min. Then, an average linear expansion coefficient (CTE) in the temperature range of 100° C. to 250° C. is determined.

The hygroscopic expansion coefficient is measured, for example, in the following manner. A polyimide resin film is formed from the polyimide precursor composition, and a test sample having a width of 5 mm and a length of 20 mm is cut out of the film. With the use of a humidity-type thermomechanical analyzer (HC-TMA4000SA available from Bruker AXS Corporation), the hygroscopic expansion coefficient of the test sample is measured under the following conditions. The test sample is sufficiently dried and maintained in a chamber at 30° C. at a humidity of 5% RH for 3 hours for stabilization. After the relative humidity is changed to 75% RH, the test sample is maintained for 3 hours for stabilization. At this time, the elongation of the test sample is measured with a tensile load of 196 mN. The hygroscopic expansion coefficient is calculated based on the elongation of the test sample and the change in relative humidity.

Next, the use of the polyimide precursor composition as a material for an insulative layer of a wiring circuit board will be described by way of example.

First, a photosensitive liquid (insulative layer material) is prepared by dissolving the specific polyimide precursor (A), at least one of the specific imide acrylate compound (B) and the specific polyethylene glycol compound (C), the pyridine photosensitive agent and, optionally, other ingredients (the sensitizer, the dissolution accelerator and the like) in an organic solvent. The amount of the organic solvent to be used at this time is preferably, for example, about 150 to 2000 parts by weight based on 100 parts by weight of the polyimide precursor (A).

The photosensitive liquid is applied onto a support base such as a silicon wafer, a ceramic plate, an aluminum plate, a stainless steel plate or a metal alloy plate so as to form a coating film preferably having a dry thickness of 1 to 30 μm, particularly preferably 5 to 20 μm.

A film of the applied photosensitive liquid is heat-dried at a temperature of not lower than 170° C., preferably at 170° C. to 200° C. for about 10 minutes, more preferably at 170° C. to 190° C. for about 10 minutes to provide the coating film. Then, the coating film is exposed to activation radiation such as ultraviolet radiation. After the exposure, the coating film is heat-treated at a reduced pressure on the order of not higher than 10 Pa at a temperature of about 200° C. to about 400° C. The polyimide precursor serving as a skeletal material is dehydrated to be cyclized into a less soluble polyimide. In this manner, an insulative layer is formed, which is free from swelling with a developing liquid or the like and excellent in patterning resolution. Thus, a board is provided, which has a double layer structure including the support base and the insulative layer formed on the support base.

On the other hand, an insulative layer is formed on a metal substrate such as a stainless steel foil in substantially the same manner as described above by using the photosensitive liquid (insulative layer material). Further, a predetermined electrically conductive circuit pattern is formed on the insulative layer by a semi-additive method. After a thin nickel film is formed on the electrically conductive circuit pattern, the photosensitive liquid (insulative layer material) is applied over the thin nickel film on the electrically conductive circuit pattern and the insulative layer by a spin coater, and then thermally dried at a temperature of not lower than 170° C., preferably at 170° C. to 200° C. for about 10 minutes, more preferably at 170° C. to 190° C. for about 10 minutes, to form a coating film. The coating film is exposed to activation radiation such as ultraviolet radiation. After the exposure, the coating film is heat-treated, for example, at about 200° C. to about 400° C. at a reduced pressure on the order of not higher than 10 Pa. Thus, the polyimide precursor serving as the skeletal material is dehydrated to be cyclized into a less soluble polyimide, whereby a polyimide resin insulative layer (cover layer) is formed as having a predetermined thickness. In this manner, a wiring circuit board is provided, which has the polyimide resin insulative layer (cover layer) formed on a surface thereof.

Exemplary light sources for the activation radiation for the exposure include a carbon arc lamp, a mercury vapor arc lamp, an ultra-high pressure mercury lamp, a high-pressure mercury lamp, a xenon lamp and other various lamps, which are capable of effectively emitting ultraviolet radiation, and a photoflood lamp and a solar lamp which are capable of effectively emitting visible light.

The dose of the activation radiation is preferably, for example, 300 to 450 mJ/cm² (at about 300 to about 450 nm), and the cumulative dose of the activation radiation is preferably 100 to 1000 mJ/cm².

Thereafter, the polyimide resin insulative layer thus formed is subjected to a polyimide (PI) etching process to be etched so as to have a desired shape (thickness). In the PI etching process, the polyimide resin insulative layer is dipped, for example, in a 20% NaOH ethanolamine solution contained in a bath kept at a temperature of about 60° C. to about 90° C.

The polyimide resin insulative layer forming method described above is applicable, for example, to production of a circuit-containing suspension board for an HDD. That is, the polyimide resin insulative layer forming method utilizing the exposure step and the like can be employed, for example, for forming flat terminal portions of flying leads formed as external connection terminals having uncovered opposite surfaces for the suspension board of the HDD.

### EXAMPLES

Next, inventive examples will be described in conjunction with comparative examples. However, it should be understood that the present invention be not limited to these inventive examples.

First, polyamic acids a to f were synthesized in the following manner.

<Synthesis of Polyamic Acid a>

An NMP solution of a polyamic acid having structural units represented by the general formulae (1) and (2) (containing the structural unit represented by the formula (2) in a proportion of 20 mol % based on the overall amount of the polyamic acid) was prepared by putting 94.15 g (320 mmol) of 3,3′,4,4′-biphenyltetracarboxylic dianhydride (BPDA), 27.68 g (256 mmol) of p-phenylenediamine (PPD), 0.50 g (64 mmol) of 2,2′-bis(trifluoromethyl)-4,4′-diaminobiphenyl (TFMB) and 874 g of N-methyl-2-pyrrolidone (NMP) in a 1000-ml four-neck flask, and stirring the resulting mixture at a room temperature (25° C.). In the general formula (1), n is 1, and m is 0.

<Synthesis of Polyamic Acids b to f>

NMP solutions of polyamic acids each having the structural units represented by the general formulae (1) and (2) were prepared in substantially the same manner as in the synthesis of the polyamic acid a, except that the proportions of the respective ingredients were changed as shown below in Table 1. The proportions (mol %) of the structural unit represented by the formula (2) based on the overall amount of the polyamic acid are also shown in Table 1. For the polyamic acids b to f, n is 1 and m is 0 in the general formula (1) as for the polyamic acid a.

TABLE 1
(g)

| | | | | Proportion (mol %) of |
|---|---|---|---|---|
| | | | | structural unit repre- |
| | BPDA | PPD | TFMB | sented by formula (2) |
| Polyamic acid a | 94.15 | 27.68 | 20.50 | 20 |
| Polyamic acid b | 94.15 | 24.22 | 30.74 | 30 |
| Polyamic acid c | 94.15 | 20.76 | 40.99 | 40 |
| Polyamic acid d | 94.15 | 17.30 | 51.24 | 50 |
| Polyamic acid e | 88.27 | 6.49 | 76.86 | 80 |
| Polyamic acid f | 35.31 | 0 | 38.43 | 100 |

### <Preparation of Photosensitive Polyamic Acid Compositions A to J>

Next, solutions of photosensitive polyamic acid compositions A to J (polyimide precursor compositions) were each prepared by blending ingredients shown below in Table 2 and the corresponding NMP solution of the polyamic acid a to f thus synthesized in proportions shown in Table 2 (based on 100 g of the polyamic acid a to f). A sensitizer, an imide acrylate compound (B) and a polyethylene glycol compound (C) shown in Table 2 for use in the preparation are as follows:

### Sensitizer

1-ethyl-3,5-dimethoxycarbonyl-4-(2-nitrophenyl)-1,4-dihydropyridine represented by the following structural formula (x):

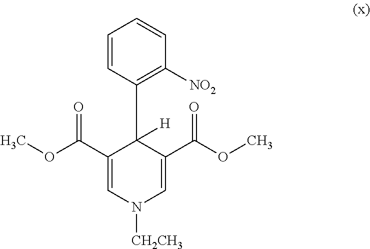

### Imide Acrylate Compound (B)

N-acryloyloxyethyl hexahydrophthalimide (ARONIX M140 available from Toagosei Co., Ltd.) represented by the following structural formula (b1):

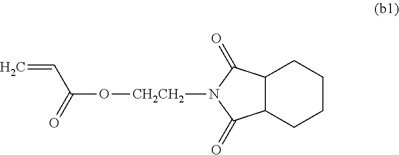

### Polyethylene Glycol Compound (C)

A polyethylene glycol compound represented by the above general formula (4) and having a weight average molecular weight of 400 g/mol. In the formula (4), R₄ is a hydroxyl group, and R₅ is a hydrogen atom. The repetition number k is an integer (k=9) corresponding to the weight average molecular weight of 400 g/mol.

TABLE 2
(g)

| Photosensitive | | Photo- | Imide | Polyethylene |
|---|---|---|---|---|
| polyamic acid | Polyamic | sensitive | acrylate | glycol |
| composition | acid | agent | compound (B) | compound (C) |
| A | b | 14 | 52 | — |
| B | c | 14 | 52 | — |
| C | c | 14 | 74 | — |
| D | c | 14 | — | 52 |
| E | d | 14 | 74 | — |
| F | e | 14 | 74 | — |
| G | a | 14 | 20 | — |
| H | b | 14 | 20 | — |
| I | c | 14 | 20 | — |
| J | f | 14 | 200 | — |

### Example 1

### <<Formation of Polyimide Resin Film>>

The solution of the photosensitive polyamic acid composition A was applied onto a 20-μm thick stainless steel foil (SUS304) by a spin coater, and then heated at 170° C. for 10 minutes to be dried. Thus, a coating film of the photosensitive polyamic acid composition A (having a thickness of 14 μm) was formed. In turn, the coating film was exposed to ultraviolet radiation (at 365 nm at 400 mJ/cm²), and then heated at 185° C. for 3 minutes. Further, the coating film was heated at a pressure of not higher than 10 Pa at 350° C. to be cured (imidized). Thus, a polyimide resin film with the stainless steel foil was prepared. Thereafter, the stainless steel foil was removed with the use of a ferric chloride solution. Thus, the polyimide resin film was prepared for property evaluation.

<<Production of Wiring Circuit Board having Polyimide Resin Cover Layer>>

On the other hand, a 10-μm thick polyimide resin layer having a linear expansion coefficient of not greater than 20 ppm/K after being cured was formed on a 20-μm thick stainless steel foil (SUS304), and then a base layer including a thin chromium film having a thickness of 30 nm and a thin copper film having a thickness of 70 nm was formed as an underlying layer over the polyimide resin layer by a sputtering deposition method. After a plating resist was formed in a pattern complementary in shape to a predetermined wiring pattern with the use of a dry film resist, an electrically conductive circuit pattern later serving as a predetermined wiring pattern was formed on a portion of the base layer not formed with the plating resist by a semi-additive copper electroplating method. The electrically conductive circuit pattern had a thickness of 14 μm, and included wirings each having a width of 12 μm and spaced 12 μm from each other. Ten wiring patterns were arranged parallel to each other as being spaced a predetermined distance from each other.

Thereafter, the plating resist and then portions of the thin chromium film and the thin copper film underlying the plating resist were chemically etched off. Then, a hard thin nickel film having a thickness of 0.1 μm was formed on a surface of the electrically conductive circuit pattern by electroless nickel plating. Thereafter, the solution of the photosensitive polyamic acid composition A was applied over the surfaces of the thin nickel film and the base layer by a spin coater, and then thermally dried at 170° C. for 10 minutes. Thus, a coating film of the photosensitive polyamic acid composition A (having a thickness of 28 μm) was formed. In turn, the coating film was irradiated with ultraviolet radiation (at a wavelength of 365 nm at a dose of 400 mJ/cm²), and then heated at 185° C. for 3 minutes. Then, the coating film was heated at a pressure of not higher than 10 Pa at 350° C. to be thereby cured (imidized), whereby a 20-μm thick cover layer of the polyimide resin was formed over the electrically conductive surface portions. Thus, a wiring circuit board having the polyimide resin cover layer was produced.

### Examples 2 to 6 and Comparative Examples 1 to 4

Polyimide resin films and wiring circuit boards respectively having polyimide resin cover layers were produced in substantially the same manner as in Example 1, except that photosensitive polyamic acid compositions shown below in Table 3 were used.

The properties (linear expansion coefficient, hygroscopic expansion coefficient and PI etchability) of the polyimide resin films thus produced were measured and evaluated. The polyimide resin cover layers of the wiring circuit boards thus produced were each visually inspected for separation in an interface between the polyimide resin cover layer and an electrically conductive portion by the following method. The results are shown below in Table 3.

### <Linear Expansion Coefficient>

An evaluation sample having a width of 5 mm and a length of 20 mm was cut out of each of the polyimide resin films. Then, measurement was performed on the sample with the use of a thermomechanical analyzer (THERMO PLUS TMA8310 available from Rigaku Corporation). Specifically, the elongation of the sample was measured along a measurement length of 15 mm in a temperature range of 100° C. to 250° C. with a tensile load of 49 mN, while the temperature was increased at a rate of 5° C./min. Then, an average linear expansion coefficient (CTE) in the temperature range of 100° C. to 250° C. was determined. A sample having a linear expansion coefficient of not greater than 25 ppm/K was rated as excellent (O), and a sample having a linear expansion coefficient of greater than 25 ppm/K was rated as unacceptable (X).

### <Hygroscopic Expansion Coefficient>

An evaluation sample having a width of 5 mm and a length of 20 mm was cut out of each of the polyimide resin films. Then, measurement was performed on the sample with the use of a humidity-type thermomechanical analyzer (HC-TMA4000SA available from Bruker AXS Corporation). Specifically, the test sample was sufficiently dried and maintained in a chamber at 30° C. at 5% RH for 3 hours for stabilization. After the relative humidity was changed to 75% RH, the test sample was maintained for 3 hours for stabilization. At this time, the elongation of the test sample was measured with a tensile load of 196 mN. The hygroscopic expansion coefficient was calculated based on the elongation of the test sample and the change in relative humidity. As a result, a sample having a hygroscopic expansion coefficient of not greater than 12 ppm/% RH was rated as excellent (o), and a sample having a linear expansion coefficient of greater than 12 ppm/% RH was rated as unacceptable (x).

### <PI Etchability>

The etchability of each of the polyimide resin films on SUS surfaces was evaluated. After the initial thickness of the polyimide resin film was measured, the polyimide resin film was immersed in an etching liquid (a solution containing 30.97 wt % of potassium hydroxide, 36.03 wt % of 2-aminoethanol and 33.00 wt % of water) kept at 80° C. with stirring. After the etching, the thickness of the polyimide resin film was measured. Based on the measurements, the PI etchability was evaluated. A film etched immediately after the immersion was rated as excellent (o), and a film requiring about 1 minute until the start of the etching after the immersion was rated as acceptable (Δ).

### <Separation>

The wiring circuit boards each having the polyimide resin cover layer were each cut by a microtome to expose a section thereof for visual inspection of an interface between the electrically conductive circuit pattern and the cover layer formed on the wiring circuit board for separation. Then, the exposed section was observed by an optical microscope to be checked for separation. As a result, a wiring circuit board free from separation was rated as excellent (o), and a wiring circuit board suffering from separation was rated as unacceptable (x).

TABLE 3

| | Photosensitive | Linear | Hygroscopic | | PI |
|---|---|---|---|---|---|
| | polyamic acid | expansion | expansion | Sepa- | etch- |
| | composition | coefficient | coefficient | ration | ability |
| Example 1 | A | ∘ | ∘ | ∘ | ∘ |
| Example 2 | B | ∘ | ∘ | ∘ | ∘ |
| Example 3 | C | ∘ | ∘ | ∘ | ∘ |
| Example 4 | D | ∘ | ∘ | ∘ | Δ |
| Example 5 | E | ∘ | ∘ | ∘ | ∘ |
| Example 6 | F | ∘ | ∘ | ∘ | ∘ |
| Comparative | G | ∘ | x | x | ∘ |
| Example 1 | | | | | |
| Comparative | H | x | ∘ | ∘ | ∘ |
| Example 2 | | | | | |
| Comparative | I | x | ∘ | ∘ | ∘ |
| Example 3 | | | | | |
| Comparative | J | x | ∘ | ∘ | ∘ |
| Example 4 | | | | | |

As apparent from the above results, the polyimide resin films of Examples 1 to 3, 5 and 6 respectively formed from the polyamic acid compositions each prepared by blending the polyamic acid having the structural unit represented by the above general formula (2) in a proportion of 30 to 80 mol % based on the overall amount of the polyamic acid and 52 to 74 g of the imide acrylate compound (B) based on 100 g of the polyamic acid each had a lower linear expansion coefficient, a lower hygroscopic expansion coefficient and excellent PI etchability. The wiring circuit boards of Examples 1 to 3, 5 and 6 were free from the separation in the interface between the electrically conductive circuit pattern and the polyimide resin cover layer formed over the substrate formed with the electrically conductive circuit pattern. The polyimide resin film of Example 4 formed from the polyamic acid composition prepared by blending the polyamic acid having the structural unit represented by the above general formula (2) in a proportion of 40 mol % based on the overall amount of the polyamic acid and 52 g of the polyethylene glycol compound (C) based on 100 g of the polyamic acid had a lower linear expansion coefficient and a lower hygroscopic expansion coefficient. Further, the wiring circuit board of Example 4 was free from the separation in the interface between the electrically conductive circuit pattern and the polyimide resin cover layer. The polyimide resin film of Example 4 was slightly poorer in PI etchability than the polyimide resin films of the other inventive examples but with no problem.

On the other hand, the polyimide resin film of Comparative Example 1 formed from the polyamic acid composition prepared by blending the polyamic acid having the structural unit represented by the above general formula (2) in a proportion of 20 mol % based on the overall amount of the polyamic acid and 20 g of the imide acrylate compound (B) based on 100 g of the polyamic acid had a lower linear expansion coefficient, but an insufficiently reduced hygroscopic expansion coefficient. Further, the wiring circuit board of Comparative Example 1 suffered from separation in the interface between the polyimide resin cover layer and the electrically conductive circuit pattern. Further, the polyimide resin films of Comparative Examples 2 and 3 respectively formed from the polyamic acid compositions each prepared by using the polyamic acid having the structural unit represented by the above general formula (2) in a proportion of 30 to 40 mol % based on the overall amount of the polyamic acid and blending 20 g of the imide acrylate compound (B) based on 100 g of the polyamic acid had an insufficiently reduced linear expansion coefficient. Further, the polyimide resin film of Comparative Example 4 formed from the polyamic acid composition prepared by using the polyamic acid having the structural unit represented by the above general formula (2) in a proportion of 100 mol % based on the overall amount of the polyamic acid and blending 200 g of the imide acrylate compound (B) had an insufficiently reduced linear expansion coefficient as in Comparative Examples 2 and 3.

The polyimide precursor composition provides a polyimide material which has a lower linear expansion coefficient and a lower hygroscopic expansion coefficient and, even if being used as a material for a cover layer to be formed on a substrate formed with an electrically conductive circuit pattern, prevents separation in an interface between the cover layer and the electrically conductive circuit pattern, and permits formation of an pattern image having excellent PI etchability. Therefore, the polyimide precursor composition is advantageously used for a circuit-containing suspension board for an HDD.

Although a specific form of embodiment of the instant invention has been described above in order to be more clearly understood, the above description is made by way of example and not as a limitation to the scope of the instant invention. It is contemplated that various modifications apparent to one of ordinary skill in the art could be made without departing from the scope of the invention which is to be determined by the following claims.

What is claimed is:

1. A polyimide precursor composition comprising:
a polyimide precursor (A),
and at least one of an imide acrylate compound (B) and a polyethylene glycol compound (C), the at least one of the compounds (B) and (C) being present in a proportion of 30 to 100 parts by weight based on 100 parts by weight of the polyimide precursor (A):
wherein the polyimide precursor (A) comprises:
(a1) a structural unit represented by the following general formula (1): 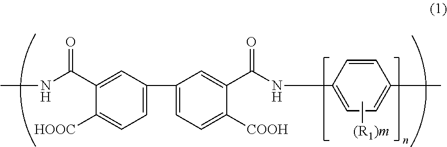
wherein R₁ is a C₁ to C₃ alkyl group and connected to an aromatic ring, m is a positive integer of 0 or not greater than 4, and n is an integer of 1 to 4; and
(a2) a structural unit represented by the following general formula (2): 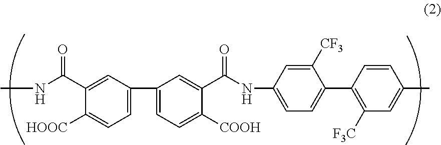
wherein the structural unit (a1) and the structural unit (a2) are present in a molar ratio of (a1)/(a2)=20/80 to 70/30;
wherein the imide acrylate compound (B) is represented by the following general formula (3): 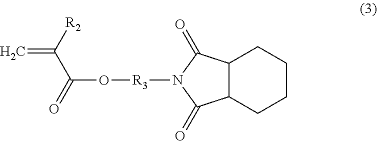
wherein R₂ is a hydrogen atom or a methyl group, and R₃ is a divalent hydrocarbon group having two or more carbon atoms; and
wherein the polyethylene glycol compound (C) is represented by the following general formula (4): 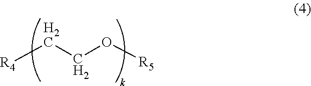
wherein R₄ is a hydroxyl group or a methoxy group, R₅ is a hydrogen atom or a methyl group, and k is a positive number of 4 to 23.

2. The polyimide precursor composition according to claim 1,
wherein the imide acrylate compound (B) is present in a proportion of 30 to 100 parts by weight based on 100 parts by weight of the polyimide precursor (A).

3. The polyimide precursor composition according to claim 1, further comprising a pyridine photosensitive agent.

4. The polyimide precursor composition according to claim 2, further comprising a pyridine photosensitive agent.

5. A wiring circuit board comprising:
a wiring circuit substrate having an electrically conductive circuit pattern provided on a surface thereof; and
a polyimide precursor composition layer formed on the surface of the wiring circuit substrate by applying a solution of the polyimide precursor composition as recited in claim 1 on the surface.

6. A wiring circuit board comprising:
a wiring circuit substrate having an electrically conductive circuit pattern provided on a surface thereof; and
a polyimide precursor composition layer formed on the surface of the wiring circuit substrate by applying a solution of the polyimide precursor composition as recited in claim 2 on the surface.

7. A wiring circuit board comprising:
a wiring circuit substrate having an electrically conductive circuit pattern provided on a surface thereof; and
a polyimide precursor composition layer formed on the surface of the wiring circuit substrate by applying a solution of the polyimide precursor composition as recited in claim 3 on the surface.

8. A wiring circuit board comprising:
a wiring circuit substrate having an electrically conductive circuit pattern provided on a surface thereof; and
a polyimide resin insulative layer formed from the polyimide precursor composition as recited in claim 1 on the surface of the wiring circuit substrate and patterned in a predetermined pattern by a wet etching process.

9. A wiring circuit board comprising:
a wiring circuit substrate having an electrically conductive circuit pattern provided on a surface thereof; and
a polyimide resin insulative layer formed from the polyimide precursor composition as recited in claim 2 on the surface of the wiring circuit substrate and patterned in a predetermined pattern by a wet etching process.

10. A wiring circuit board comprising:
a wiring circuit substrate having an electrically conductive circuit pattern provided on a surface thereof; and
a polyimide resin insulative layer formed from the polyimide precursor composition as recited in claim 3 on the surface of the wiring circuit substrate and patterned in a predetermined pattern by a wet etching process.
